(19) United States
(12) Patent Application Publication
(10) Pub. No.: US 2010/0193899 A1
(43) Pub. Date: Aug. 5, 2010

(54) PRECISE OXIDE DISSOLUTION

(75) Inventor: Oleg Kononchuk, Theys (FR)

Correspondence Address: WINSTON & STRAWN LLP;PATENT DEPARTMENT, 1700 K STREET, N.W., WASHINGTON, DC, 20006, US

(73) Assignee: S.O.I.TEC SILICON ON INSULATOR TECHNOLOGIES, Bernin (FR)

(21) Appl. No.: 12/677,083

(22) PCT Filed: Nov. 23, 2007
(86) PCT No.: PCT/IB07/55392

§ 371 Date: Mar. 8, 2010

(51) Int. Cl. H01L 29/06; H01L 21/306

(52) U.S. Cl. 257/506; 438/689; 257/E29.006; 257/E21.215

(57) ABSTRACT

In a Semiconductor-on-Insulator (SeOI) wafer that includes a thin working layer made from one or more semiconductor material(s); a support layer, and a buried oxide (BOX) layer between the working layer and the support layer, a method of decreasing the thickness of the BOX layer by dissolving it at a dissolution rate that is controlled and set to be below 0.06 Å/sec in order to avoid increasing Dit. The Dit after dissolution of the BOX layer is typically below 1E12 cm-2 eV-1.

The invention concerns a method for dissolving the buried oxide layer of a SeOI (Semiconductor-On-Insulator) wafer in order to decrease the thickness of said buried oxide layer. The invention also concerns a SeOI wafer obtained after dissolving the buried oxide of a starting SeOI wafer by such a method.

A SeOI wafer is understood in this text as a wafer comprising:
a thin working layer made from one or more semiconductor material(s), such as silicon,
a support layer, and
a buried oxide (BOX) layer between the working layer and the support layer.

The invention is particularly well adapted for producing SeOI wafers having a BOX which is an Ultra Thin Buried Oxide (UTBOX) layer. In this text a UTBOX layer is understood as a buried BOX having a thickness which is less than 500 Å.

SeOI wafers with an UTBOX layer are becoming a material of choice for modern advanced CMOS applications.

A promising method for manufacturing SeOI wafers with an UTBOX layer implies dissolving the BOX of a starting SeOI wafer, in order to bring the thickness of said BOX down to a desired value.

Some attempts for dissolving the BOX of a SeOI wafer have requested annealing the starting wafer at over 1300° C. for several hours. Such attempts were therefore not adapted to an industrial processing of the wafers.

WO2006/059586 discloses a method for completely dissolving the BOX of a starting SeOI wafer. In this method the SeOI wafer is annealed at a temperature which is preferably over 1100° C., in an atmosphere which is made e.g. of Argon or hydrogen. The starting SeOI has a working Si layer which is thicker than 150 nm (1500 Å) in order to prevent the excessive formation of a particular type of defects known as voids. This document therefore discloses potentially interesting information for enhancing the quality of the wafers obtained.

However, quality issues remain to be solved concerning SeOI wafers having a BOX which has been thinned by dissolution.

In particular, the Dit of the SeOI obtained is representative of the electrical quality of the wafer obtained. The Dit is related to the interface trap density. It characterizes the interface between the working layer and the BOX layer.

It is an object of the invention to provide a quality SeOI, in particular with an UTBOX layer, having a good (i.e. low) Dit. A low Dit can in this text be understood as a Dit under 1E12 cm⁻² eV⁻¹.

It would also be desirable to obtain, if possible, the SeOI wafers with a yield compatible with usual industrial conditions.

It is another object of the invention to provide a method for manufacturing quality SeOI with an UTBOX layer and a low Dit.

Still another object of the invention is to provide a method which is compatible with high volume SeOI wafer manufacturing.

To this end, the present invention provides a method and a SeOI wafer according to the claims.

Other features, objects and advantages of the invention shall be understood in greater detail in reading the following description, which is illustrated by the following figures:

FIG. 1 shows a model of BOX dissolution in Argon ambient, and especially oxygen distribution in SeOI wafer during anneal,

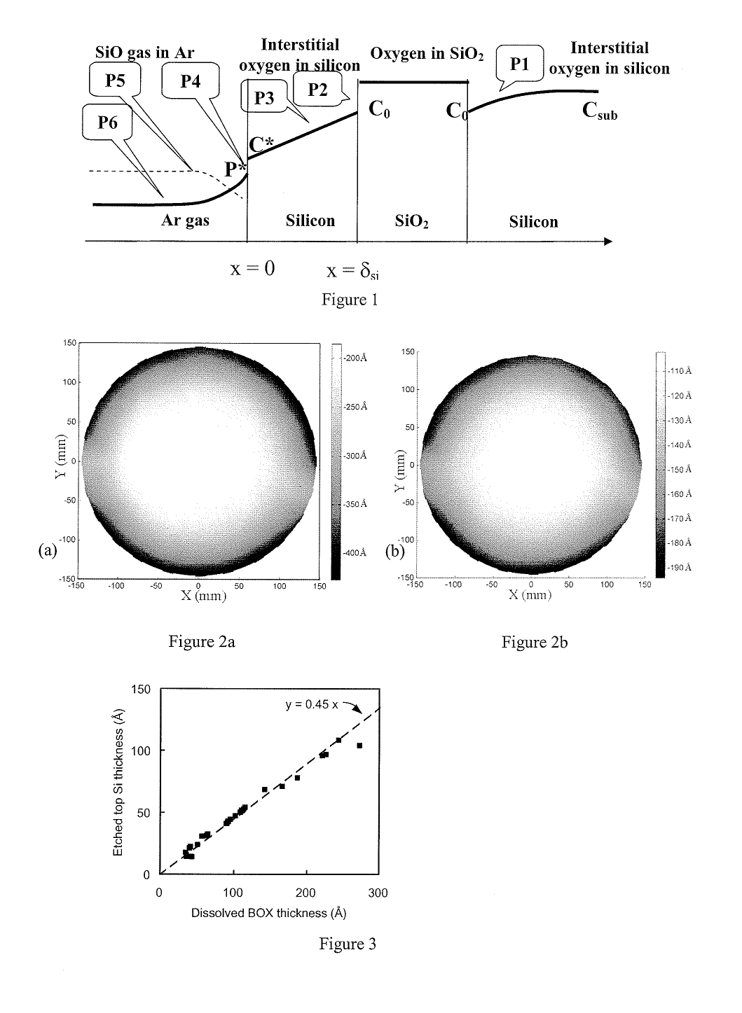

FIGS. 2a and 2b are, respectively, maps of the dissolved BOX thickness and etched Si thickness over a SeOI wafer annealed at 1200° C. for 1 hour,

FIG. 3 is a graph showing the evolution of the amount of etched top Si in a SeOI as a function of the thickness of dissolved BOX measured in the same locations of the SeOI,

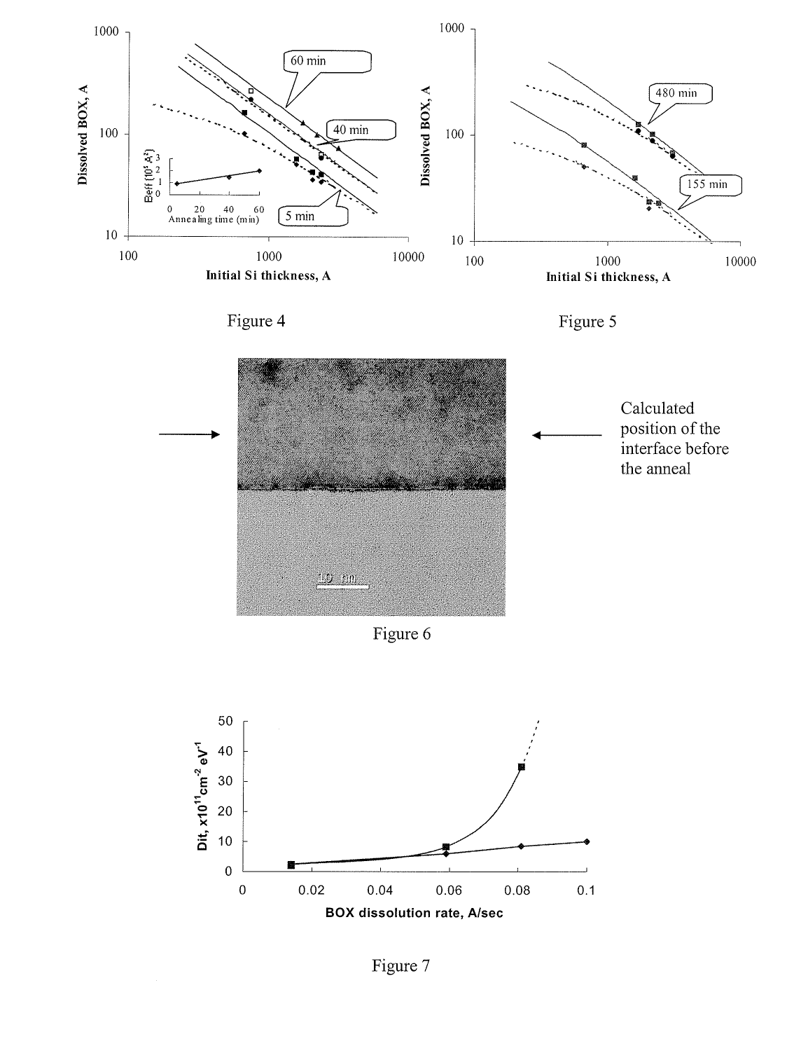

FIG. 4 is a graph showing the evolution of the thickness of dissolved BOX in a SeOI as a function of the thickness of the top Si layer and the annealing time at 1200° C.,

FIG. 5 is a graph showing the evolution of the thickness of dissolved BOX in a SeOI as a function of the thickness of the top Si layer and the annealing time at 1150° C.,

FIG. 6 is a cross sectional TEM image of an annealed SeOI wafer, showing in particular the amount of BOX dissolved after annealing,

FIG. 7 is a graph showing the evolution of the Dit associated to a SeOI having undergone annealing for dissolving its BOX, as a function of the BOX dissolution rate obtained during the annealing,

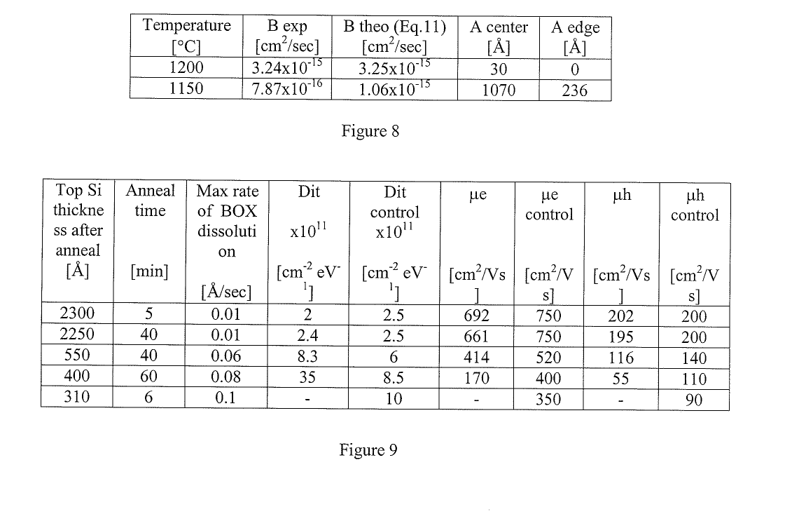

FIG. 8 is a table showing linear and parabolic coefficients used in a model of BOX dissolution in Argon ambient,

FIG. 9 is a table gathering electrical parameters extracted from Pseudo-MOSFET measurements, associated with SeOI having dissolution annealing under different conditions.

Annealing of SeOI wafer is carried out in an atmosphere which is substantially oxygen-free, such as an atmosphere of pure Argon or hydrogen or their mixture, and preferably in pure Argon with Oxygen content below 1 ppm.

In the case of a SeOI having a thin top layer (inferior to about 500 nm) (e.g. in Si), the BOX dissolution is determined by oxygen transport through the top layer and evaporation from the surface, rather than diffusion into the base wafer. Using non oxidized ambient can increase dissolution rate.

With reference to FIG. 1, a model of BOX dissolution in Argon ambient and at high temperature is described hereafter.

There are several processes Pi, which define oxide dissolution rate in steady-state conditions:

P1. Diffusion of interstitial oxygen Oᵢ from the base wafer, which leads to growth of buried oxide at the BOX/base interface

P2. Decomposition of the BOX at the BOX/top Si interface into Oᵢ and Si, which results in Si epitaxial regrowth at the top interface

P3. Diffusion of interstitial oxygen through the top Si layer

P4. Reaction of Oᵢ with silicon at the top Si surface resulting in volatile SiO

Si+Oᵢ→SiO(g) (1)

P5. Etching of the top Si layer by residual oxygen contamination in the annealing atmosphere, which competes with the reaction (1)

O₂+Si→SiO₂

SiO₂+2 Si→2 SiO(g) (2)

P6. Gas phase SiO transport through Argon ambient.

More precisely, in steady-state conditions the oxide dissolution rate is determined by the slowest of the mechanisms of the oxygen transport from the oxide.

If oxygen is considered to be in equilibrium at the SiO₂/Si interfaces and if interstitial oxygen concentration at the interfaces is equal to oxygen solid solubility at the anneal temperature, process P1 can be neglected. Indeed, flux of oxygen atoms J₁ coming from the base substrate is decreasing with time t:

$${J}_{1} = ( {C}_{sub} - {C}_{0} ) \sqrt{\frac{D}{π t}} , \qquad ( 3 )$$

while diffusion flux J₂ through the top Si layer is constant:

$${J}_{2} = \frac{D ( {C}_{0} - {C}^{*} )}{{δ}_{si}} , \qquad ( 4 )$$

where C₀, D is interstitial oxygen solubility and diffusivity in silicon [14], δₛᵢ is the thickness of top Si layer and C*, C_{sub} is the interstitial oxygen concentration at the top Si surface and in the base wafer, respectively.

Estimations for the top Si thickness of approximately 0.1 μm show that the flux J₂ will be larger than J₁ already after 1 sec anneal at 1200° C. We can also assume that oxide decomposition/epitaxial Si regrowth is fast and is not a limiting factor of oxide dissolution kinetics. This assumption is supported by the literature data on oxygen precipitation kinetics, where it was found that oxygen precipitate dissolution is diffusion limited rather than reaction limited process.

Chemical reaction (1) is the first order reaction if the effect of residual partial pressure of oxygen in Argon is neglected. So, proportional relation between concentration of interstitial oxygen at the top surface C* and partial pressure of SiO in Argon at the top surface P* can be written:

C*=K P*. (5)

Transfer of SiO from Si surface through Argon can be described by mixed gas diffusion and forced convection. The mass transfer coefficient k will depend on geometry of the system, gas parameters, temperature and thickness of boundary layer, which depends on local gas velocity:

J₃=kP*· (6)

Finally, for each dissolved molecule of buried oxide one silicon atom is removed from the top Si layer through evaporation of SiO. Thus, Si top layer will be etched with the rate proportional to the BOX etching rate:

Δδ_{box}=(Nₛᵢ/Nₛᵢₒ₂)Δδₛᵢ, (7)

where Nₛᵢ=5×10²² cm⁻³, and Nₛᵢₒ₂=2.3×10²² cm⁻³. Taking into account that Si atom flux can be expressed through top silicon layer thickness

$${J}_{3} = - 2 {N}_{si} \frac{d {δ}_{si}}{d t} \qquad ( 8 )$$

and combining equations (4)-(8) leads to differential equation for the Si layer thickness with the solution:

$$\frac{{δ}_{si}^{2} - {δ}_{0}^{2}}{2 Dt} + \frac{( {δ}_{si} - {δ}_{0} )}{{k}^{*} t} + \frac{{C}_{0}}{2 {N}_{si}} = 0 , \qquad ( 9 )$$

where δ₀ is initial thickness of the top Si layer at t=0 and k* is simply equal to k/K. This equation can be rewritten in the form of classical linear-parabolic model:

$$\begin{matrix}{δ}_{si}^{2} + A {δ}_{si} = B ( τ - t ) \\ with & ( 10 ) \\ A = \frac{2 D}{{k}^{*}} , B = \frac{D {C}_{0 }}{{N}_{si}} , τ = \frac{{δ}_{0}^{2} + A {δ}_{0}}{B} . & ( 11 )\end{matrix}$$

There could be two limiting cases for oxide dissolution. When mass transport through gas ambient is fast, dissolution is limited by interstitial oxygen diffusion and the dissolution rate is inversely proportional to the top Si layer thickness. In the other case of gas transport limited regime, the dissolution rate depends only on temperature and local mass transport coefficient k*. According to this model, the dissolution rate of the BOX does neither depend on the BOX thickness nor on the base wafer material.

FIG. 2 to 9 show results from different experiments carried out to assess SeOI wafers processed under different conditions.

300 mm commercially available SOI wafers produced by Smart Cut™ technique were used. Buried oxide was prepared by thermal oxidation of the donor Si wafers in atmosphere of oxygen with H₂O, resulting in the bonding interface at the BOX/base wafer interface. Interstitial oxygen concentration in the base wafers was 1.2×10¹⁸ cm⁻³ as determined by FTIR spectroscopy with a calibration constant of 4.8×10¹⁷ cm⁻². Wafers were annealed in Argon atmosphere in vertical furnaces, specially designed to reduce residual oxygen gas contamination. Four different types of furnaces were tested with the equivalent results. Concentration of oxygen gas in the exhaust was below 5 ppm during anneal. Annealing was performed at 1100° C.-1200° C. for a time from a few minutes to a few hours. For all the experiments, the same slow temperature ramps were used to minimize slip generation at high temperatures. Thickness of top Si and BOX layers varied in the range of 500-5000 Å and 150-1500 Å, respectively.

FIG. 2 shows maps of thickness difference before and after 1 hour annealing at 1200° C. for BOX (a) and top Si (b) layers. Thickness of the layers before the annealing was 1450 Å and 500 Å, respectively.

Thickness of the layers before and after the dissolution was measured by a spectroscopic ellipsometer. 49 data points with 5 mm edge exclusion were taken for each wafer. A three-layer model with standard dispersion functions for Si and SiO₂ was used and showed a very good fit of the spectra. Few samples were analyzed by XTEM and XRR (X-ray reflection) to confirm ellipsometry data. Thickness of the layers determined by these techniques agreed well within the accuracy of the techniques.

It is clearly seen that the dissolution of buried oxide occurs at 1200° C., when interstitial oxygen in the substrate is supersaturated. The patterns of dissolved BOX and top silicon layer correlate very well with each other and with the distribution of gas flow in the vertical furnace. Dissolution rate of oxide and etching rate of Si are higher where gas velocity is higher indicating that the process occurs in the mixed diffusion/gas transport regime.

FIG. 3 shows proportionality between dissolved BOX thickness and etched top Si layer thickness. Each point represents thickness measurements for different wafers annealed at 1200° C. for different times, averaged at the positions with the constant radius. The data fit very well to the straight line with the slope of 45%, which is the ratio of specific volumes of Si and SiO₂, as predicted by Eq. 7. This points out that no additional Si etching takes place due to the reaction (2) at 1200° C., indicating high quality of annealing ambient.

A temperature above 1150° C. is therefore suitable for BOX dissolution, and preferably a temperature of 1200° C.

Experimental dependence of dissolved BOX thickness on the initial thickness of the top Si layer is shown in the FIGS. 4 and 5 for 1200° C. and 1150° C. annealing, respectively. Solid lines are theoretical fit of the Eq. 10 and Eq. 7 for the edge points and dashed lines for the center points.

It appears that dissolution characteristics are better in the case of anneal temperature of 1200° C. than that of 1150° C. An also anneal time in the case of temperature condition above 1150° C. is more compatible with high volume manufacturing of SOI wafers, and preferably a temperature of 1200° C.

For each annealing condition the same value of B, but different A were used to fit edge and center data. B and A are coefficients as shown in Eq. 10. To account for the BOX dissolution during long temperature ramp, the data for each annealing time and temperature were fit with separate effective coefficients Aeff and Beff, but center and edge points for the same annealing conditions were fit with the same value of Beff.

As all the anneals had the same ramp profiles, it is possible to extract isothermal values of the coefficients B and A by plotting the dependence of Beff (and Beff/Aeff, respectively) on holding time at the temperature of the anneal as shown in the insert of FIG. 4. The slope of the curve will give the value of B (more precisely, this linearity is valid in the case of small etched Si thickness only). Results of the fitting of the parameters together with the theoretical values of B are presented in FIG. 8.

At 1200° C. dissolution of the BOX at the wafer edge is limited by the interstitial oxygen diffusion in the top Si layer with excellent agreement between experimental and theoretical B value calculated from Eq. 11.

As expected, at the wafer center, gas transport slows down dissolution, resulting in higher A values (A center values of 30 Å and 1070 Å vs. A edge values of 0 Å and 236 Å, respectively at 1200° C. and 1150° C.). With a temperature decrease, dissolution rate kinetics slow down and significantly deviate from diffusion-limited regime, but still show a gas velocity pattern.

Also, initial Si thickness appears to have an influence on dissolution rate. The thinner the initial Si thickness is, the faster the dissolution rate.

FIG. 6 presents TEM image of top Si/BOX interface of SOI wafer annealed in Argon at 1200° C. for 1 hr. Roughness of the Si/SiO₂ interface is 2-3 atomic planes, which is comparable with the roughness of SOI interfaces before the anneal (and typical for thermal oxides). No crystallographic defect has been found in the top Si layer or at the boundary of regrown Si layer.

Pseudo-MOSFET technique is very sensitive to interface quality of the top SeOI interface. Therefore electrical characterization of the top Si layer and top interface was carried out by a Pseudo-MOSFET technique.

This technique uses the particular structure of SeOI wafers to produce MOSFET-like current transport characteristics. A bias ramp is applied on the substrate, which acts as a transistor gate.

The buried oxide serves as gate oxide and two metallic probes applied on the film act as source and drain. Because the source and drain are not doped, the device can be operated as an n-MOS as well as a p-MOS transistor. The typical parameters, hole and electron mobility (μh and μe), subthreshold swing (S), interface trap density (D_{IT}), flat-band and threshold voltages (V_{FB} and V_{T}) can be extracted in a similar way to fully processed MOSFETs. For all measurements, the source is grounded, the drain is biased at a low value (200 mV) to insure linear mode operation and the gate voltage (V_{G}) is swept from 0V towards accumulation (inversion) to extract majority (minority) carrier characteristics (respectively).. Set of samples annealed in different conditions was measured by Pseudo-MOSFET method to assess the electrical quality of the interface and of the regrown Si. Values of hole and electron mobility were extracted from the curve

$$\frac{{I}_{D}}{\sqrt{Gm}} {vs V}_{G}$$

where Gm is the transconductance

$$\frac{\partial {I}_{D}}{\partial {V}_{G}} ,$$

as described in. S is taken as the inverse of the subthreshold slope of the Log(I_{D}) vs V_{G} curve. Interface trap density is calculated from S using the equation:

$${D}_{IT} = \frac{{C}_{OX}}{q} [ \frac{S}{\frac{kT}{q} log ( 10 )} - ( 1 + \frac{{C}_{Si}}{{C}_{OX}} ) ] , \qquad ( 12 )$$

where q is the elementary charge, kT/q is the thermal potential, Cₛᵢ and Cₒₓ are the film and buried oxide capacitance respectively. FIG. 9 summarizes the results of Pseudo-MOSFET measurements.

Because the top surface of the Si film is not passivated during the measurement, the extracted parameters depend on the top Si film thickness. Therefore, for a valid comparison, results are given also for the equivalent wafers, which have not undergone BOX dissolution treatment. The thinnest sample annealed did not reveal transistor behaviour, indicating that the highest dissolution rate resulted in bad quality of the interface.

Results of Dit dependence on the BOX dissolution rate are plotted on the FIG. 7. In FIG. 7, square symbols refer to the measurements of samples with different Si layer thickness and diamonds symbols refer to the measurements of control samples with the same Si layer thickness, but without annealing.

Control samples results abscissa are virtual since the examples did not undergo any annealing; therefore no BOX dissolution rates are available. They were plotted to ease comparison with samples that underwent annealing.

From FIG. 7 and FIG. 9, it is clearly seen that interface trap density increases and carrier mobility decreases with increasing BOX dissolution rate, while annealing time or amount of the dissolved BOX seem to have little or no effect. We could speculate that the high rate of solid phase Si regrowth can result in defects at Si/SiO₂ interface, but for the BOX dissolution rate below 0.06 Å/sec electrical quality of annealed SOI structures is comparable with the reference wafers with Dit values below 1E12 cm⁻²e⁻¹. The lower the Dit value is, the better the electric quality of the wafer is.

Therefore, according to an aspect of the invention the dissolution rate is controlled to be kept at a limited value, under 0.06 angstroms/sec.

This aspect of the invention goes against the natural tendency one could have to maximize the dissolution rate in order to speed up the process.

In order to keep the dissolution rate compatible with industrial applications, the maximum value mentioned above should be respected but the dissolution rate should be kept not too low. As an example, a dissolution rate below 0.01Å/sec is not compatible with high volume manufacturing. The dissolution rate should therefore preferably be kept above this value.

Significant reduction of buried oxide thickness without degradation of the wafer quality can be achieved by annealing of the SeOI wafers in oxygen free ambient. Oxide dissolution rate is determined by interstitial oxygen diffusion through the top Si layer and inversely depends on top Si thickness.

Generally speaking, the applicant has determined that the control of the dissolution rate was obtained in the first place by controlling the following parameters:
the control of the atmosphere under which dissolution is carried out, and/or
the control of the temperature under which dissolution is carried out, and/or
the choice of the thickness of said working layer.

When anneal is carried out in non oxidized ambient such as Argon with less than 1 ppm oxygen (or more generally an atmosphere with less than 1 ppm oxygen), high rate oxide dissolution is possible and can be controlled by temperature and initial top Si thickness.

More precisely, optimal oxide dissolution rate in Argon ambient is controlled by setting anneal temperature above 1150° C. and selecting initial top Si thickness between 550 and 2300 Å.

1-8. (canceled)

9. In a Semiconductor-on-Insulator (SeOI) wafer that includes a thin working layer made from one or more semiconductor material(s); a support layer, and a buried oxide (BOX) layer between the working layer and the support layer, the improvement which comprises decreasing the thickness of the BOX layer by dissolving it at a dissolution rate that is controlled and set to be below 0.06 Å/sec in order to avoid increasing Dit.

10. The invention of claim 9, wherein the dissolution rate is further set to be above about 0.01 Å/sec.

11. The invention of claim 9, wherein dissolution rate is controlled by controlling the atmosphere under which dissolution is carried out.

12. The invention of claim 11, wherein the atmosphere is controlled so as to contain less than 1 ppm oxygen.

13. The invention of claim 9, wherein dissolution rate is controlled by controlling the temperature under which dissolution is carried out.

14. The invention of claim 11, wherein the temperature is controlled so as to be above 1150° C.

15. The invention of claim 9, wherein dissolution rate is controlled by selecting the thickness of the working layer.

16. The invention of claim 15, wherein the thickness of the working layer is selected so as to be between 550 and 2300 Å.

17. The invention of claim 9, wherein the Dit after dissolution of the BOX layer is below 1E12 cm-2 eV-1.

18. A Semiconductor-on-Insulator (SeOI) wafer comprising a thin working layer made from one or more semiconductor material(s); a support layer; and a buried oxide (BOX) layer of reduced thickness between the working layer and the support layer, with the SeOI wafer having a Dit below 1E12 cm-2 eV-1.

19. The SeOI wafer of claim 18, wherein the reduced thickness of the BOX layer is below 200 Å.
